(19) United States
(12) Patent Application Publication
(10) Pub. No.: US 2011/0012171 A1
(43) Pub. Date: Jan. 20, 2011

(54) SEMICONDUCTOR DEVICE

(75) Inventor: Masakazu KOBAYASHI, Hyogo-ken (JP)

Correspondence Address: PATTERSON & SHERIDAN, L.L.P., 3040 POST OAK BOULEVARD, SUITE 1500, HOUSTON, TX, 77056, US

(73) Assignee: KABUSHIKI KAISHA TOSHIBA, Tokyo (JP)

(21) Appl. No.: 12/831,991

(22) Filed: Jul. 7, 2010

(30) Foreign Application Priority Data
Jul. 15, 2009 (JP) 2009-166968

(51) Int. Cl. H01L 29/739

(52) U.S. Cl. 257/139; 257/E29.198

(57) ABSTRACT

According to one embodiment, a semiconductor device includes a first semiconductor layer of a first conductivity type, a second semiconductor layer of a second conductivity type, a third semiconductor layer of the first conductivity type, and a first main electrode. The second semiconductor layer is provided on the first semiconductor layer. The third semiconductor layer is provided on the first semiconductor layer in contact with the second semiconductor layer and has an impurity concentration higher than an impurity concentration of the first semiconductor layer. The first main electrode includes a first metal layer and a second metal layer made of a metal different from a metal of the first metal layer. The first metal layer is connected to the second semiconductor layer. The second metal layer is connected to the third semiconductor layer.

### CROSS-REFERENCE TO RELATED APPLICATIONS

This application is based upon and claims the benefit of priority from the prior Japanese Patent Application No. 2009-166968, filed on Jul. 15, 2009; the entire contents of which are incorporated herein by reference.

### FIELD

Embodiments described herein relate generally to a semiconductor device.

### BACKGROUND

It is desirable to reduce the ON resistance of power semiconductor devices to reduce the power consumption. To this end, insulated gate bipolar transistors (hereinbelow “IGBTs”), which have both the high input impedance characteristics of a MOSFET and the low output impedance characteristics of a bipolar transistor, have been used. An IGBT has an insulated gate similar to that of a MOSFET and conductivity modulation characteristics similar to those of a bipolar transistor.

To downsize, a pn shorted collector IGBT including a collector short region also has been used as an IGBT with a freewheeling diode (hereinbelow “FWD”) integrated therein. Conventionally, and in the case of a collector structure having such a pn shorted collector, the collector had been formed using the same metal to provide ohmic junctions with the semiconductors.

On the other hand, it has been proposed to select the metal of the junction according to the conductivity type of the semiconductor to obtain a good ohmic junction between the semiconductor and the metal.

### BRIEF DESCRIPTION OF THE DRAWINGS

FIG. 1 is a schematic cross-sectional view illustrating the configuration of a semiconductor device according to an embodiment of the invention;

FIG. 2 is a schematic cross-sectional view illustrating another configuration of the semiconductor device according to the embodiment of the invention;

FIG. 3 is a schematic cross-sectional view illustrating another configuration of the semiconductor device according to the embodiment of the invention;

FIG. 4 is a schematic cross-sectional view illustrating another configuration of the semiconductor device according to the embodiment of the invention;

FIG. 5 is a schematic cross-sectional view illustrating another configuration of the semiconductor device according to the embodiment of the invention; and

FIG. 6 is a schematic cross-sectional view illustrating another configuration of the semiconductor device according to the embodiment of the invention.

### DETAILED DESCRIPTION

In general, according to one embodiment, a semiconductor device includes a first semiconductor layer of a first conductivity type, a second semiconductor layer of a second conductivity type, a third semiconductor layer of the first conductivity type, and a first main electrode. The second semiconductor layer is provided on the first semiconductor layer. The third semiconductor layer is provided on the first semiconductor layer in contact with the second semiconductor layer and has an impurity concentration higher than an impurity concentration of the first semiconductor layer. The first main electrode includes a first metal layer and a second metal layer made of a metal different from a metal of the first metal layer. The first metal layer is connected to the second semiconductor layer. The second metal layer is connected to the third semiconductor layer.

Exemplary embodiments of the invention will now be described in detail with reference to the drawings.

The drawings are schematic or conceptual; and the relationships among the configurations and the lengthwise and crosswise dimensions of portions, the proportions of sizes among portions, etc., are not necessarily the same as the actual values thereof. Further, the dimensions and proportions may be illustrated differently among the drawings, even for identical portions.

In the specification and the drawings of the application, components similar to those described in regard to a drawing thereinabove are marked with like reference numerals, and a detailed description is omitted as appropriate.

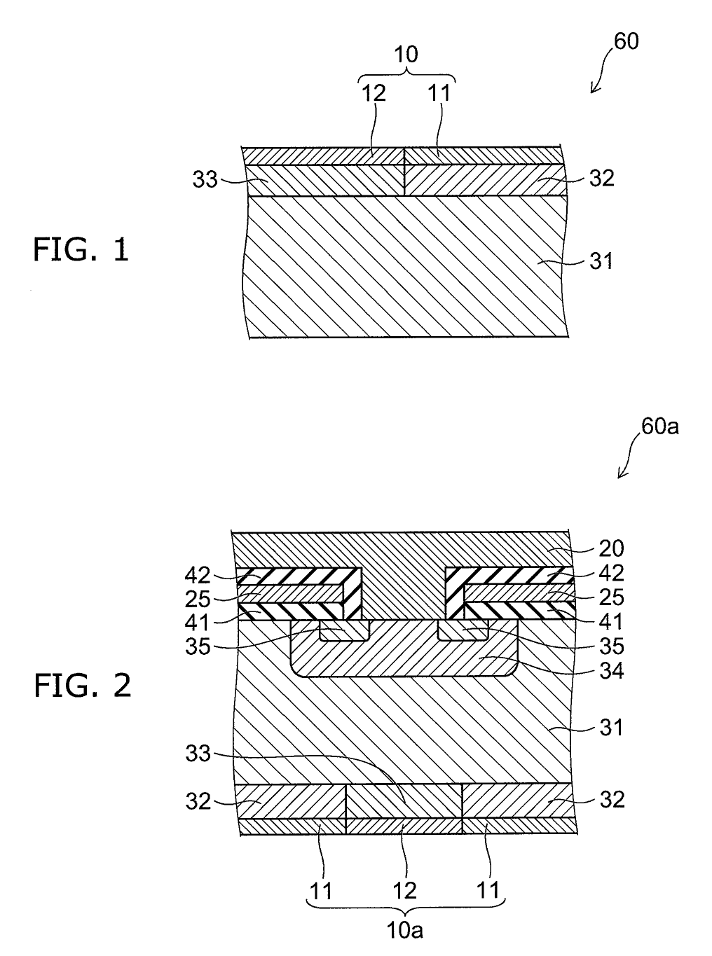

FIG. 1 is a schematic cross-sectional view illustrating the configuration of a semiconductor device according to an embodiment of the invention.

In a semiconductor device 60 as illustrated in FIG. 1, a p-type second semiconductor layer 32 is provided on an n⁻-type first semiconductor layer 31. An n⁺-type third semiconductor layer 33 is provided on the n⁻-type first semiconductor layer 31 in contact with the p-type second semiconductor layer 32. The n⁺-type third semiconductor layer 33 has an impurity concentration higher than that of the n⁻-type first semiconductor layer 31.

A first metal layer 11 is provided on the p-type second semiconductor layer 32. A second metal layer 12 is provided on the n⁺-type third semiconductor layer 33. The first metal layer 11 and the second metal layer 12 are made of mutually different metals. In other words, the first metal layer 11 and the second metal layer 12 are made of mutually different single metals or are made of alloys having mutually different compositions.

In the case where the semiconductor layers 32 and 33 are made of silicon, the first metal layer 11 is formed of, for example, aluminum (Al) and the second metal layer 12 is formed of, for example, titanium (Ti). The first and second metal layers 11 and 12 may be formed by, for example, vacuum vapor deposition, sputtering, and the like.

The first metal layer 11 and the second metal layer 12 are electrically connected and form a first main electrode 10.

Junctions having low contact resistances, and desirably ohmic junctions, are formed between the first metal layer 11 and the p-type second semiconductor layer 32 and between the second metal layer 12 and the n⁺-type third semiconductor layer 33.

Accordingly, the contact resistance between the second semiconductor layer 32 and the first metal layer 11 is lower than the contact resistance between the second semiconductor layer 32 and the second metal layer 12. Also, the contact resistance between the third semiconductor layer 33 and the second metal layer 12 is lower than the contact resistance between the third semiconductor layer 33 and the first metal layer 11.

The resistance (the contact resistance) of the junction portion between a metal and a semiconductor depends on the height of the Schottky barrier due to the difference between the work function of the metal and the electron affinity, i.e., the energy difference from the bottom of the conduction band to the vacuum state, of the semiconductor. The resistance also depends on the surface state due to the discontinuity at the interface between the metal and the semiconductor, etc.

Optimal metals for obtaining good ohmic junctions with p-type and n-type semiconductors include, for example, aluminum (Al) for p-type silicon and titanium (Ti) for n-type silicon.

Conventionally, however, an electrode of a single metal, e.g., aluminum (Al), has been used for both p-type and n-type semiconductors. In other words, methods have included increasing the impurity concentration of the n-type silicon to reduce the contact resistance of the junction with the electrode even when aluminum (Al) was used.

However, in such methods, it is not easy to form ohmic junctions having sufficiently low contact resistances. Therefore, the contact resistance between the semiconductor and the electrode cause the ON voltage and the like of the semiconductor device to worsen and the performance as a semiconductor device to decrease.

For example, in the case of a shorted collector IGBT such as that illustrated in FIG. 2, the ON voltage when single metals of aluminum (Al) and titanium (Ti) are used as the first main electrode are 1.5 V and 1.8 V, respectively. In the case of an IGBT and an FWD formed in anti-parallel, the ON voltages when aluminum (Al) and titanium (Ti) are used as the first main electrode are 1.2 V and 1.1 V, respectively.

Accordingly, in the case where the optimal metal is used for each of the p-type and n-type semiconductors, e.g., aluminum (Al) for the p-type semiconductor and titanium (Ti) for the n-type semiconductor, it can be inferred that the ON voltage of the IGBT will be 1.5 V and the ON voltage of the FWD will be 1.1 V.

Thus, in the semiconductor device 60 of this example, the first main electrode 10 can be formed by selecting an optimal first metal layer 11 and second metal layer 12 to obtain good ohmic junctions with the p-type and n-type semiconductors, respectively. Therefore, in this example, the undesirable increase of the ON voltage and the like can be suppressed.

The case is illustrated in the semiconductor device 60 where the first conductivity type is the n-type and the second conductivity type is the p-type. Also, the case is illustrated where silicon is used as the semiconductor.

However, the invention is not limited thereto. The first conductivity type may be the p-type; and the second conductivity type may be the n-type.

Although in the semiconductor device 60, one first main electrode 10 made of the first metal layer 11 provided on the p-type second semiconductor layer 32 and the second metal layer 12 provided on the n⁺-type third semiconductor layer 33 is illustrated, the invention is not limited thereto.

The first main electrode 10 may be multiply provided with similar structures; and other diffusion regions, insulating films, etc., may be included in the n⁻-type first semiconductor layer 31.

FIG. 2 is a schematic cross-sectional view illustrating another configuration of the semiconductor device according to the embodiment of the invention.

In a semiconductor device 60a as illustrated in FIG. 2, a p-type fourth semiconductor layer 34 is provided in the n⁻-type first semiconductor layer 31. An n⁺-type fifth semiconductor layer 35 is provided in the p-type fourth semiconductor layer 34. The n⁺-type fifth semiconductor layer 35 has an impurity concentration higher than that of the n⁻-type first semiconductor layer 31.

A control electrode 25 is provided on the n⁻-type first semiconductor layer 31, the p-type fourth semiconductor layer 34, and the n⁺-type fifth semiconductor layer 35 via an insulating film 41.

A second main electrode 20 is provided on the p-type fourth semiconductor layer 34 and the n⁺-type fifth semiconductor layer 35 in isolation from the control electrode 25. In this example, the second main electrode 20 is provided also on the control electrode 25 via an insulating film 42. The second main electrode 20 is formed of, for example, aluminum (Al).

The p-type second semiconductor layer 32 is provided on the bottom face of the n⁻-type first semiconductor layer 31, i.e., the face on the side opposite to the p-type fourth semiconductor layer 34.

The n⁺-type third semiconductor layer 33 is provided on the bottom face of the n⁻-type first semiconductor layer 31 at a position opposing the p-type fourth semiconductor layer 34 and in contact with the p-type second semiconductor layer 32. The n⁺-type third semiconductor layer 33 has an impurity concentration higher than that of the n⁻-type first semiconductor layer 31.

The first metal layer 11 is provided on the face of the p-type second semiconductor layer 32 on the side opposite to the n⁻-type first semiconductor layer 31. The second metal layer 12 is provided on the face of the n⁺-type third semiconductor layer 33 on the side opposite to the n⁻-type first semiconductor layer 31.

The second and third semiconductor layers 32 and 33 and the first and second metal layers 11 and 12 are similar to those of the semiconductor device 60.

The first metal layer 11 and the second metal layer 12 are electrically connected and form a first main electrode 10a.

In the semiconductor device 60a, an IGBT is formed between the second main electrode 20 and the first metal layer 11; and an FWD is formed and connected in anti-parallel between the second main electrode 20 and the second metal layer 12. Thus, the semiconductor device 60a is a shorted collector IGBT having the first main electrode 10a as a collector electrode, the second main electrode 20 as an emitter electrode, and the control electrode 25 as a gate electrode.

In the semiconductor device 60a, ohmic junctions are formed between the first metal layer 11 and the p-type second semiconductor layer 32 and between the second metal layer 12 and the n⁺-type third semiconductor layer 33.

Accordingly, the first main electrode 10a has an ohmic junction with each of the p-type second semiconductor layer 32 and the n⁺-type third semiconductor layer 33.

Therefore, in the semiconductor device 60a, the first and second main electrodes 10a and 20 can be formed by selecting optimal metals to obtain good ohmic junctions with the p-type and n-type silicon. For example, the first and second metal layers 11 and 12 may include aluminum (Al) for the p-type silicon and titanium (Ti) for the n-type silicon, respectively.

Thus, in the semiconductor device 60a of this example, the undesirable increase of the ON voltage of the IGBT element and the ON voltage of the FWD element can be suppressed.

The case is illustrated in this example where the first conductivity type is the n-type and the second conductivity type is the p-type. Also, the case is illustrated where silicon is used as the semiconductor. However, the invention is not limited thereto. The first conductivity type may be the p-type; and the second conductivity type may be the n-type.

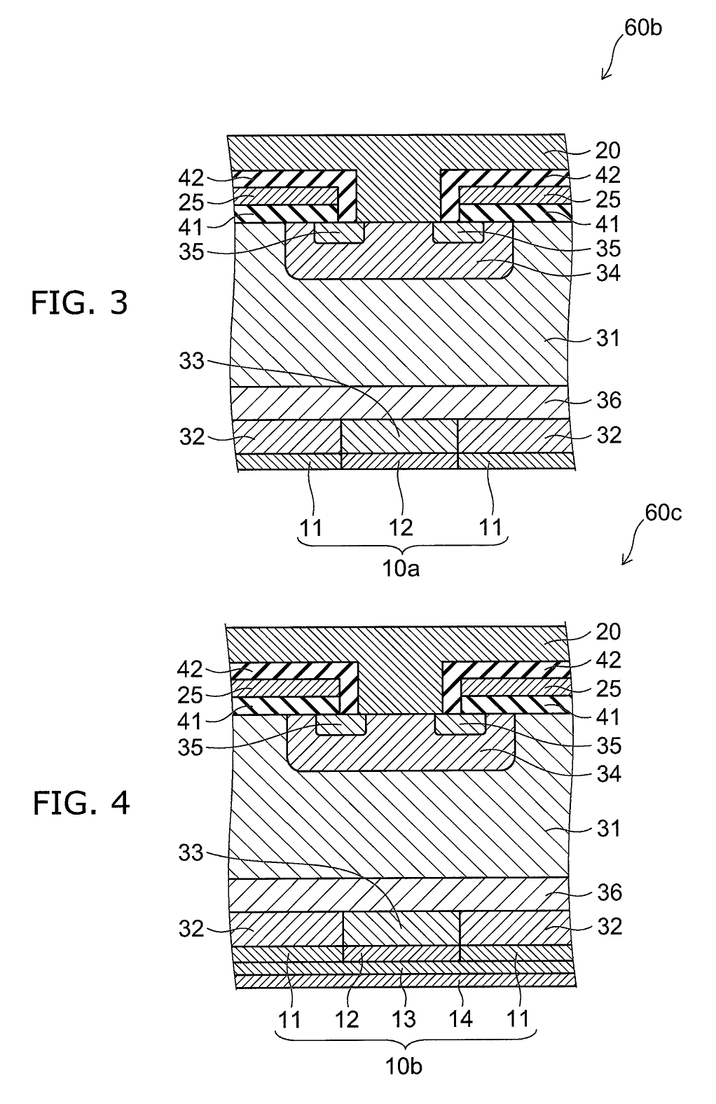

FIG. 3 is a schematic cross-sectional view illustrating another configuration of the semiconductor device according to the embodiment of the invention.

In a semiconductor device 60b of this example as illustrated in FIG. 3, an n⁺-type sixth semiconductor layer 36 is provided between the n⁻-type first semiconductor layer 31 and the p-type second semiconductor layer 32 and between the n⁻-type first semiconductor layer 31 and the n⁺-type third semiconductor layer 33. Otherwise, the semiconductor device 60b is similar to the semiconductor device 60a illustrated in FIG. 2 and is a shorted collector IGBT having the first main electrode 10a as a collector electrode, the second main electrode 20 as an emitter electrode, and the control electrode 25 as a gate electrode.

As illustrated in FIG. 3, so-called punch-through can be prevented by providing the n⁺-type sixth semiconductor layer 36. In other words, the depletion layer of the n⁻-type first semiconductor layer 31 that occurs when a reverse voltage is applied between the second main electrode 20 and the first main electrode 10a stops at the n⁺-type sixth semiconductor layer 36; and punch-through is prevented.

Thus, in the case where a reverse voltage is applied, the depletion layer of the n⁻-type first semiconductor layer 31 does not reach the p-type second semiconductor layer 32. Therefore, the thickness of the n⁻-type first semiconductor layer 31 can be reduced; and the ON resistance can be reduced even more

FIG. 4 is a schematic cross-sectional view illustrating another configuration of the semiconductor device according to the embodiment of the invention.

As illustrated in FIG. 4, a semiconductor device 60c of this example further includes a third metal layer 13 and a fourth metal layer 14 provided on the first metal layer 11 and the second metal layer 12. The first to fourth metal layers 11 to 14 are electrically connected and form a first main electrode 10b. Otherwise, the semiconductor device 60c is similar to the semiconductor device 60b illustrated in FIG. 3 and is a shorted collector IGBT having the first main electrode 10b as a collector electrode, the second main electrode 20 as an emitter electrode, and the control electrode 25 as a gate electrode.

Metals including, for example, nickel (Ni) and gold (Au) may be used as the third metal layer 13 and the fourth metal layer 14, respectively.

Thus, according to the first main electrode 10b having a multilayered structure, good ohmic junctions can be provided between the first metal layer 11 and the p-type second semiconductor layer 32 and between the second metal layer 12 and the n⁺-type third semiconductor layer 33, respectively. Simultaneously, active metals that react easily can be protected by providing a surface layer including a metal such as, for example, gold (Au) having a low ionization tendency.

Although the third and fourth metal layers 13 and 14 of this example are provided on the first and second metal layers 11 and 12, the invention is not limited thereto. The first main electrode may be formed by providing the third metal layer 13 on the first and second metal layers 11 and 12 and electrically connecting the first to third metal layers 11 to 13. Also, the first main electrode may be formed by providing more metal layers.

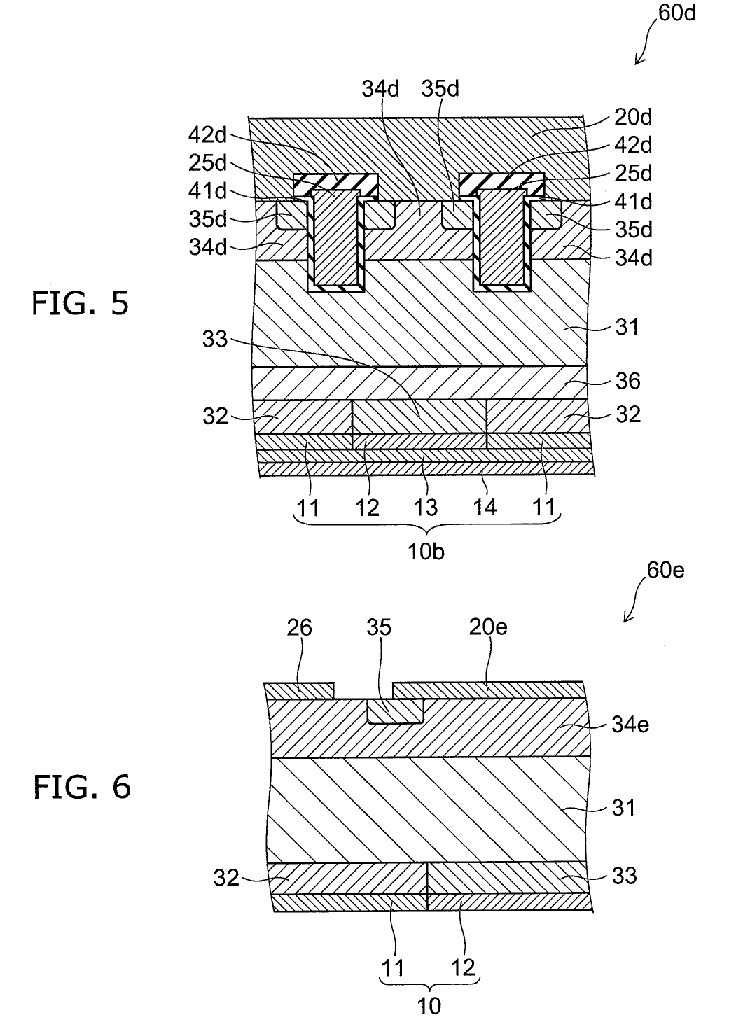

FIG. 5 is a schematic cross-sectional view illustrating another configuration of the semiconductor device according to the embodiment of the invention.

As illustrated in FIG. 5, a semiconductor device 60d of this example differs from the semiconductor device 60c illustrated in FIG. 4 in that a control electrode 25d has a trench gate structure. Otherwise, the semiconductor device 60d is similar to the semiconductor device 60c.

In other words, in the semiconductor device 60d, a p-type fourth semiconductor layer 34d is provided on the n⁻-type first semiconductor layer 31. An n⁺-type fifth semiconductor layer 35d is provided on the p-type fourth semiconductor layer 34d. The n⁺-type fifth semiconductor layer 35d has an impurity concentration higher than that of the n⁻-type first semiconductor layer 31.

The control electrode 25d pierces the p-type fourth semiconductor layer 34d and the n⁺-type fifth semiconductor layer 35d and is filled with an insulating film 41d interposed to reach the n⁻-type first semiconductor layer 31.

A second main electrode 20d is provided on the p-type fourth semiconductor layer 34d and the n⁺-type fifth semiconductor layer 35d in isolation from the control electrode 25d. In this example, the second main electrode 20d is formed also on the control electrode 25d via an insulating film 42d. The second main electrode 20d is formed of, for example, aluminum (Al).

The bottom face of the n⁻-type first semiconductor layer 31, i.e., the face on the side opposite to the p-type fourth semiconductor layer 34d on which the first main electrode 10b is provided, is similar to that of the semiconductor device 60c. The semiconductor device 60d is a shorted collector IGBT having the first main electrode 10b as a collector electrode, the second main electrode 20d as an emitter electrode, and the control electrode 25d as a gate electrode.

In the semiconductor device 60d of this example as well, the first and second main electrodes 10b and 20d can be formed by selecting optimal metals to obtain good ohmic junctions with the p-type and n-type silicon. Therefore, in this example, the undesirable increase of the ON voltage of the IGBT element and the ON voltage of the FWD element can be suppressed.

Further, by providing the first main electrode 10b with a multilayered structure, good ohmic junctions can be provided between the first metal layer 11 and the p-type second semiconductor layer 32 and between the second metal layer 12 and the n⁺-type third semiconductor layer 33. Simultaneously, active metals that react easily can be protected by providing a surface layer including a metal such as, for example, gold (Au) having a low ionization tendency.

FIG. 6 is a schematic cross-sectional view illustrating another configuration of the semiconductor device according to the embodiment of the invention.

In a semiconductor device 60e as illustrated in FIG. 6, a p-type fourth semiconductor layer 34e is provided on the n⁻-type first semiconductor layer 31. The n⁺-type fifth semiconductor layer 35 is provided in the p-type fourth semiconductor layer 34e. The n⁺-type fifth semiconductor layer 35 has an impurity concentration higher than that of the n⁻-type first semiconductor layer 31.

A control electrode 26 is provided on the p-type fourth semiconductor layer 34e.

A second main electrode 20e is provided on the p-type fourth semiconductor layer 34e and the n⁺-type fifth semiconductor layer 35 in isolation from the control electrode 26. The second main electrode 20e is formed of, for example, aluminum (Al).

The n⁺-type third semiconductor layer 33 is provided on the bottom face of the n⁻-type first semiconductor layer 31, i.e., the face on the side opposite to the p-type fourth semiconductor layer 34e. The n⁺-type third semiconductor layer 33 has an impurity concentration higher than that of the n⁻-type first semiconductor layer 31.

The p-type second semiconductor layer 32 is provided on the bottom face of the n⁻-type first semiconductor layer 31 at a position opposing the n⁺-type fifth semiconductor layer 35 and in contact with the n⁺-type third semiconductor layer 33.

The first metal layer 11 is provided on the face of the p-type second semiconductor layer 32 on the side opposite to the n⁻-type first semiconductor layer 31. The second metal layer 12 is provided on the face of the n⁺-type third semiconductor layer 33 on the side opposite to the n⁻-type first semiconductor layer 31.

The second and third semiconductor layers 32 and 33 and the first and second metal layers 11 and 12 are similar to those of the semiconductor device 60.

The first metal layer 11 and the second metal layer 12 are electrically connected and form the first main electrode 10.

In this example, a thyristor is formed between the second main electrode 20e and the first metal layer 11; and an FWD is formed and connected in anti-parallel between the second main electrode 20e and the second metal layer 12. Thus, the semiconductor device 60e of this example is a reverse conducting thyristor having the first main electrode 10 as an anode electrode, the second main electrode 20e as a cathode electrode, and the control electrode 26 as a gate electrode.

In the semiconductor device 60e, ohmic junctions are provided between the first metal layer 11 and the p-type second semiconductor layer 32 and between the second metal layer 12 and the n⁺-type third semiconductor layer 33.

Accordingly, the first main electrode 10 has ohmic junctions with the p-type second semiconductor layer 32 and the n⁺-type third semiconductor layer 33.

Therefore, in the semiconductor device 60e as well, the first and second main electrodes 10 and 20e can be formed by selecting optimal metals to obtain good ohmic junctions with the p-type and n-type silicon. For example, the first and second metal layers 11 and 12 may include aluminum (Al) for the p-type silicon and titanium (Ti) for the n-type silicon.

Thus, in the semiconductor device 60a of this example, an undesirable increase of the ON voltage of the thyristor element and the ON voltage of the FWD element can be suppressed.

The case is illustrated in this example where the first conductivity type is the n-type and the second conductivity type is the p-type. Also, the case is illustrated where silicon is used as the semiconductor. However, the invention is not limited thereto. The first conductivity type may be the p-type; and the second conductivity type may be the n-type.

Hereinabove, exemplary embodiments of the invention are described with reference to specific examples. However, the invention is not limited to these specific examples. For example, one skilled in the art may appropriately select specific configurations of components of semiconductor devices from known art and similarly practice the invention. Such practice is included in the scope of the invention to the extent that similar effects thereto are obtained.

Further, any two or more components of the specific examples may be combined within the extent of technical feasibility; and are included in the scope of the invention to the extent that the purport of the invention is included.

Moreover, all semiconductor devices practicable by an appropriate design modification by one skilled in the art based on the semiconductor devices described above as exemplary embodiments of the invention also are within the scope of the invention to the extent that the purport of the invention is included.

Furthermore, various modifications and alterations within the spirit of the invention will be readily apparent to those skilled in the art. All such modifications and alterations should therefore be seen as within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device, comprising:
a first semiconductor layer of a first conductivity type;
a second semiconductor layer of a second conductivity type provided on the first semiconductor layer;
a third semiconductor layer of the first conductivity type provided on the first semiconductor layer in contact with the second semiconductor layer, the third semiconductor layer having an impurity concentration higher than an impurity concentration of the first semiconductor layer; and
a first main electrode including a first metal layer and a second metal layer made of a metal different from a metal of the first metal layer, the first metal layer being connected to the second semiconductor layer, the second metal layer being connected to the third semiconductor layer.

2. The device according to claim 1, wherein
a contact resistance between the second semiconductor layer and the first metal layer is lower than a contact resistance between the second semiconductor layer and the second metal layer, and
a contact resistance between the third semiconductor layer and the second metal layer is lower than a contact resistance between the third semiconductor layer and the first metal layer.

3. The device according to claim 1, further comprising a third metal layer to cover the first metal layer and the second metal layer.

4. The device according to claim 3, wherein the third metal layer includes nickel or gold.

5. The device according to claim 1, wherein
the first conductivity type is an n-type and the second conductivity type is a p-type, and
the first metal layer includes aluminum and the second metal layer includes titanium.

6. The device according to claim 1, further comprising:
a fourth semiconductor layer of the second conductivity type provided on a side of the first semiconductor layer opposite to the first main electrode;
a fifth semiconductor layer of the first conductivity type provided selectively in a surface of the fourth semiconductor layer, the fifth semiconductor layer having an impurity concentration higher than the impurity concentration of the first semiconductor layer;
a control electrode provided on the first semiconductor layer, the fourth semiconductor layer, and the fifth semiconductor layer via an insulating film; and
a second main electrode provided in contact with the fourth semiconductor layer and the fifth semiconductor layer and in isolation from the control electrode.

7. The device according to claim 6, wherein
a contact resistance between the second semiconductor layer and the first metal layer is lower than a contact resistance between the second semiconductor layer and the second metal layer, and
a contact resistance between the third semiconductor layer and the second metal layer is lower than a contact resistance between the third semiconductor layer and the first metal layer.

8. The device according to claim 6, further comprising a third metal layer to cover the first metal layer and the second metal layer.

9. The device according to claim 8, wherein the third metal layer includes nickel or gold.

10. The device according to claim 6, wherein
the first conductivity type is an n-type and the second conductivity type is a p-type, and
the first metal layer includes aluminum and the second metal layer includes titanium.

11. The device according to claim 6, further comprising a sixth semiconductor layer of the first conductivity type provided between the first semiconductor layer and the second semiconductor layer and between the first semiconductor layer and the third semiconductor layers, the sixth semiconductor layer having an impurity concentration higher than the impurity concentration of the first semiconductor layer.

12. The device according to claim 1, further comprising:
a fourth semiconductor layer of the second conductivity type provided on a side of the first semiconductor layer opposite to the first main electrode;
a fifth semiconductor layer of the first conductivity type provided selectively in a surface of the fourth semiconductor layer, the fifth semiconductor layer having an impurity concentration higher than the impurity concentration of the first semiconductor layer;
a control electrode filled into a trench with an insulating film interposed, the trench piercing the fourth semiconductor layer and the fifth semiconductor layer to reach the first semiconductor layer; and
a second main electrode connected to the fourth semiconductor layer and the fifth semiconductor layer.

13. The device according to claim 12, wherein
a contact resistance between the second semiconductor layer and the first metal layer is lower than a contact resistance between the second semiconductor layer and the second metal layer, and
a contact resistance between the third semiconductor layer and the second metal layer is lower than a contact resistance between the third semiconductor layer and the first metal layer.

14. The device according to claim 12, further comprising a third metal layer to cover the first metal layer and the second metal layer.

15. The device according to claim 12, wherein
the first conductivity type is an n-type and the second conductivity type is a p-type, and
the first metal layer includes aluminum and the second metal layer includes titanium.

16. The device according to claim 12, further comprising a sixth semiconductor layer of the first conductivity type provided between the first semiconductor layer and the second semiconductor layer and between the first semiconductor layer and the third semiconductor layers, the sixth semiconductor layer having an impurity concentration higher than the impurity concentration of the first semiconductor layer.

17. The device according to claim 1, further comprising:
a fourth semiconductor layer of the second conductivity type provided on a side of the first semiconductor layer opposite to the first main electrode;
a fifth semiconductor layer of the first conductivity type provided selectively in a surface of the fourth semiconductor layer, the fifth semiconductor layer having an impurity concentration higher than the impurity concentration of the first semiconductor layer;
a control electrode provided on the fourth semiconductor layer; and
a second main electrode provided in contact with the fourth semiconductor layer and the fifth semiconductor layer and in isolation from the control electrode.

18. The device according to claim 17, wherein
a contact resistance between the second semiconductor layer and the first metal layer is lower than a contact resistance between the second semiconductor layer and the second metal layer, and
a contact resistance between the third semiconductor layer and the second metal layer is lower than a contact resistance between the third semiconductor layer and the first metal layer.

19. The device according to claim 17, further comprising a third metal layer to cover the first metal layer and the second metal layer.

20. The device according to claim 17, wherein
the first conductivity type is an n-type and the second conductivity type is a p-type, and
the first metal layer includes aluminum and the second metal layer includes titanium.
